(19) United States
(12) Patent Application Publication
(10) Pub. No.: US 2003/0092257 A1
(43) Pub. Date: May 15, 2003

(54) Method for fabricating metal interconnects

(76) Inventor: Chih-Hsien Cheng, Chang Hua Hsien (TW)

Correspondence Address: J.C. Patents, Inc., Suite 250, 4 Venture, Irvine, CA, 92618, US

(21) Appl. No.: 09/997,353

(22) Filed: Nov. 27, 2001

(30) Foreign Application Priority Data
Nov. 9, 2001 (TW) 90127832

(51) Int. Cl. H01L 21/4763

(52) U.S. Cl. 438/633

(57) ABSTRACT

A method for fabricating metal interconnects, in which a dielectric layer is formed over a substrate and then an opening is formed in the dielectric layer, is described. A metal layer is formed to fill the opening and then a protective layer is form on the surface of the metal layer by an electrochemical method. Thereafter, the protective layer and the metal layer outside the opening are removed to complete the metal interconnect process. Since the protective layer is more stable than the metal layer so that oxidation of the metal layer can be prevented, the queue time (Q-time) between the metal deposition process and the chemical mechanical polishing (CMP) process can be increased with more flexibility.

### CROSS-REFERENCE TO RELATED APPLICATION

This application claims the priority benefit of Taiwan application serial no. 90127832, filed November 9, 2001.

### BACKGROUND OF THE INVENTION

1. Field of Invention

The present invention relates to a semiconductor process. More particularly, the present invention relates to a method for fabricating metal interconnects.

2. Description of Related Art

The integration of IC devices increases to a great extent by adopting the deep sub-micron semiconductor process. However, the properties and the materials of the devices bring about some problems in the deep sub-micron semiconductor process. One problem needing to be solved instantly is that the resistance and the electromigration resistivity of the conventional aluminum interconnects do not meet the requirements for the deep sub-micron semiconductor process.

Though the techniques for fabricating aluminum interconnects in IC devices have been well developed, the interconnects are usually made from copper, instead of aluminum, in the deep sub-micron semiconductor process. The reasons for using copper interconnects are, the copper interconnects, by comparing with the aluminum interconnects, have an electromigration resistivity 30˜100 times higher, a resistance 30% lower, and a via impedance 10˜20 times lower. Therefore, the RC delay effect of a sub-micron semiconductor device can be reduced and the electromigration resistivity of the device can be improved by forming copper interconnects with low-K inter-metal dielectrics (IMD).

Since it is not easy to etch copper, the copper interconnects are mostly fabricated by the damascene techniques. In a damascene process, a dielectric layer is formed over a substrate and then patterned to form damascene openings that expose the regions with the conductive parts. After that, a barrier layer is formed in the damascene openings and then a copper layer is formed to fill the damascene openings and to connect with the conductive parts. The copper layer outside the damascene openings are then removed by chemical mechanical polishing (CMP) to form the damascene structures.

However, in the damascene process described above, the copper layer tends to be continuously oxidized during the Q-time (the period between the copper deposition process and the CMP process), so that the resistance of the copper layer is raised and the performance of the device is consequently reduced.

### SUMMARY OF THE INVENTION

Accordingly, this invention provides a method for fabricating metal interconnects, wherein the copper layer is prevented from being continuously oxidized. The queue time (Q-time) between the copper deposition process and the CMP process thus can be increased with more flexibility.

In the method for fabricating metal interconnects provided in this invention, a dielectric layer is formed over a substrate and then patterned to form an opening therein. A metal layer is formed to fill the opening and then a protective layer is formed on the metal layer by an electrochemical method. After that, the protective layer and the metal layer outside the opening is removed to complete the metal interconnect process.

In the present invention, the protective layer formed by an electrochemical method comprises cuprous oxide (Cu₂O), which is more stable than copper, so as to protect the copper layer from continuous oxidation. Consequently, the performance of the metal interconnects can be maintained and the queue time (Q-time) between the copper deposition process and the CMP process can be increased with more flexibility.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1A˜1C illustrate the process flow of fabricating metal interconnects according to a preferred embodiment of this invention; and

FIG. 2 is a schematic view of the electroplating apparatus used in the preferred embodiment of this invention.

### DESCRIPTION OF THE PREFERRED EMBODIMENTS

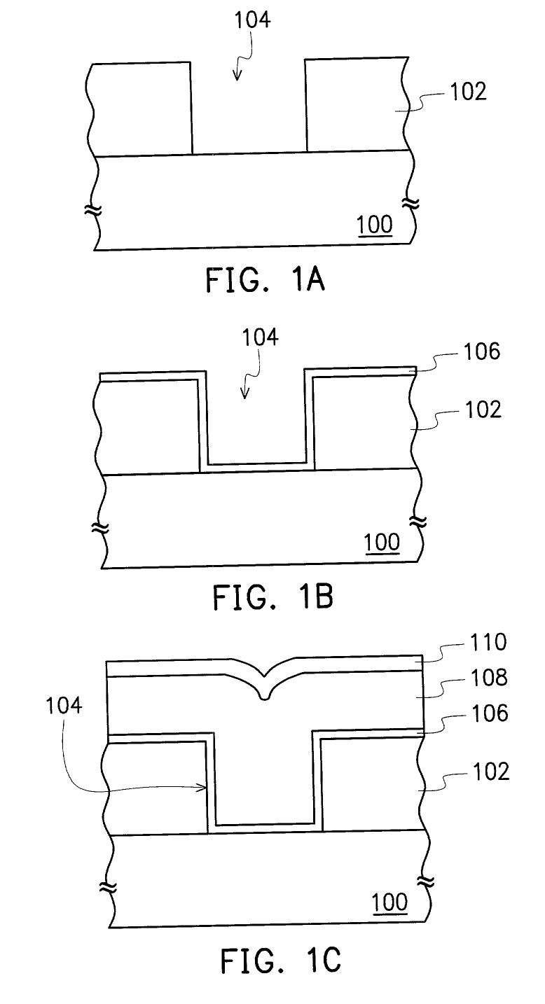

Refer to FIG. 1A˜1C, FIG. 1A˜1C illustrate the process flow of fabricating metal interconnects according to a preferred embodiment of this invention.

As shown in FIG. 1A, a substrate 100, such as a silicon substrate, is provided. The substrate 100 can be a semiconductor wafer with semiconductor devices formed thereon (not shown) and may also includes some metal interconnects (not shown).

Subsequently, a dielectric layer 102 is formed on the substrate 100. The dielectric layer 102 comprises a material such as silicon oxide, a low-K material, or other dielectric materials and is formed by, for example, chemical vapor deposition (CVD) or spin-on coating.

Still referring to FIG. 1A, a portion of the dielectric layer 102 is then removed by conducting a lithography-etching process to form an opening 104 that exposes a region of the substrate 100, which is intended to be electrically connected with the subsequently formed metal layer. The region can be the contact region of a device in the substrate 100, the contact region of a conductive line, or the top region of a plug, while the opening 104 can be correspondingly a contact hole, a via hole for disposing a plug, or a trench. The opening 104 may also be a dual damascene opening (not shown exactly).

Refer to FIG. 1B, a conformal barrier layer 106 is then deposited over the substrate 100. The barrier layer 106 comprises, for example, tantalum nitride, titanium nitride, or titanium silicon nitride and is formed by a method such as (a) nitrification of a metal layer that has just been formed or (b) reactive sputtering. In method (a) a tantalum layer is formed on the wafer by magnetron DC sputtering and then the wafer is placed in an atmosphere containing nitrogen or ammonia, so as to convert the tantalum layer into a tantalum nitride layer. In method (b) tantalum atoms are sputtered from a target and then react with active nitrogen species within a plasma of an argon-nitrogen mixture, tantalum nitride is thereby formed and deposited on the wafer.

Refer to FIG. 1C, a metal layer 108, such as a copper layer, is then formed on the barrier layer 106 to fill the opening 104. The metal layer 108 can be formed by a method such as physical vapor deposition (PVD), chemical vapor deposition (CVD) or sputtering.

Subsequently, a stable protective layer 110 is formed on the surface of the metal layer 108. The protective layer 110 comprises a material such as cuprous oxide (Cu₂O) and is formed by an electrochemical method, for example. If the protective layer 110 were absent, the metal layer 108 would be continuously oxidized, resulting in a higher resistance and compromising the performance of the device.

The next step is to remove the protective layer 110 and a portion of the metal layer 108 and the barrier layer 106 outside the opening 104 by chemical mechanical polishing (CMP) so as to complete the metal interconnect process. Since one skilled in the art can easily figure out the result of this step from FIG. 1C, another drawing is deemed unnecessary.

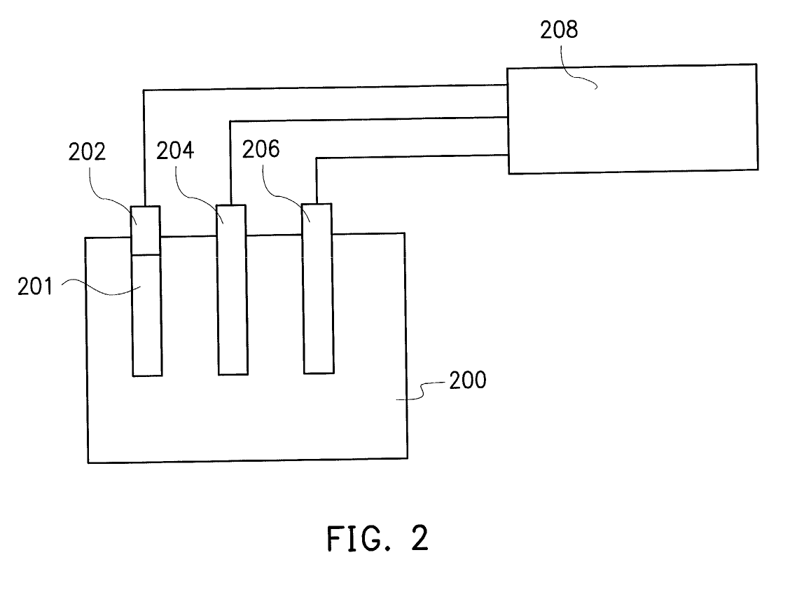

Refer to FIG. 2, which schematically illustrates an electroplating apparatus used in the preferred embodiment of this invention, for understanding the method of forming the cuprous oxide layer on the copper layer in the preferred embodiment.

As shown in FIG. 2, the electroplating apparatus includes an electroplating cell 200, a working electrode 202, a reference electrode 204, a counter electrode 206, and a power source 208, wherein the working electrode 202 electrically connects with the wafer 201 having a copper layer (not shown) formed thereon. During the electroplating process, the working electrode 202 is applied with a voltage, such as −250 mV, to form a more stable cuprous oxide (Cu₂O) layer on the copper layer. The composition of the electroplating solution contained in the electroplating cell 200 comprises, for example, an aqueous solution containing 0.1 M dibasic sodium phosphate (Na₂HPO₄) and 10% methanol (CH₃OH) and having a pH value of 7˜9. Since cuprous oxide is more stable than copper, the copper layer is protected from continuous oxidation and the queue time (Q-time) between the copper deposition process and the CMP process can be increased with more flexibility.

It is to be understood that this invention can also be applied to the cases in which other active metals rather than copper are used as the materials of the interconnects despite the interconnects are made from copper in the preferred embodiment of the invention.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A method for fabricating metal interconnects, comprising the steps of:
providing a substrate on which a dielectric layer is formed;
forming an opening in the dielectric layer;
forming a metal layer on the substrate to fill the opening;
forming a protective layer on the metal layer; and
removing the protective layer and the metal layer outside the opening.

2. The method of claim 1, wherein the opening comprises a dual damascene opening.

3. The method of claim 1, wherein the opening comprises a trench.

4. The method of claim 1, wherein the opening comprises a via hole.

5. The method of claim 1, wherein the opening comprises a contact hole.

6. The method of claim 1, wherein the opening comprises a damascene opening.

7. The method of claim 1, wherein the metal layer comprises copper.

8. The method of claim 1, wherein the protective layer comprises cuprous oxide (Cu₂O).

9. The method of claim 1, wherein the protective layer is formed by an electrochemical method that uses an electroplating solution comprising an aqueous solution containing 0.1M dibasic sodium phosphate (Na₂HPO₄) and 10% methanol (CH₃OH).

10. The method of claim 9, wherein the electroplating solution has a pH value of about 7 to about 9.

11. The method of claim 1, further comprising forming a conformal barrier layer on the substrate after the opening is formed and before the metal layer is formed.

12. A method for fabricating metal interconnects, comprising the steps of:
providing a substrate with a dielectric layer formed thereon;
forming an opening in the dielectric layer;
forming a copper layer on the substrate to fill the opening;
forming a cuprous oxide protective layer on a surface of the copper layer; and
removing the cuprous oxide protective layer and the copper layer outside the opening.

13. The method of claim 12, wherein the opening comprises a dual damascene opening.

14. The method of claim 12, wherein the opening comprises a trench.

15. The method of claim 12, wherein the opening comprises a via hole.

16. The method of claim 12, wherein the opening comprises a contact hole.

17. The method of claim 12, wherein the opening comprises a damascene opening.

18. The method of claim 12, wherein forming the cuprous oxide protective layer comprises an electrochemical method.

19. The method of claim 18, wherein an electroplating solution used in the electrochemical method for forming the cuprous oxide protective layer comprises an aqueous solution containing 0.1M dibasic sodium phosphate (Na₂HPO₄) and 10% methanol.

20. The method of claim 19, wherein the electroplating solution has a pH value of about 7 to about 9.
